(19) United States
(12) Patent Application Publication
(10) Pub. No.: US 2011/0151190 A1
(43) Pub. Date: Jun. 23, 2011

(54) SHADOW EDGE LITHOGRAPHY FOR NANOSCALE PATTERNING AND MANUFACTURING

(76) Inventors: Jae-Hyun Chung, Bellevue, WA (US); Guofeng Bai, Redmond, WA (US); Woon-Hong Yeo, Seattle, WA (US)

(21) Appl. No.: 12/599,286

(22) PCT Filed: May 8, 2008
(86) PCT No.: PCT/US08/63113

§ 371 Date: Nov. 6, 2009

Related U.S. Application Data
(60) Provisional application No. 60/916,777, filed on May 8, 2007.

(51) Int. Cl. B32B 5/16; G03F 7/20; B82Y 30/00

(52) U.S. Cl. 428/143; 430/324; 977/773

(57) ABSTRACT

An advanced high-resolution and high-throughput shadow edge (116) lithography (SEL) method is disclosed for forming uniform zero- one- and two-dimensional nanostructures on a substrate. The method entails high-vacuum oblique vapor deposition and a compensated shadow effect of a pre-patterned layer (100). A method of compensating for cross-substrate variation is also disclosed. The compensation approach enables routine, low-cost fabrication of uniform nanoscale features, or nanogaps (110) on the order of 10 nm±1 nm, that can be used to etch nanowells (196) or to form nanostructures such as nanowires (169), using a selective metal lift-off process. A wafer-scale analytical model is proposed for predicting the width of nanogaps (110) fabricated by the shadow effect on pre-patterned edges. By combining compensation and pattern reversal techniques with multiple shadow patterning, two-dimensional structures such as crossing nanowires may be generated. A technique is disclosed for smoothing edge roughness of the nanostructures.

### RELATED APPLICATION

This application claims the benefit under 35 U.S.C. §119(e) from U.S. Provisional Patent Application No. 60/916,777, filed May 8, 2007, which is incorporated herein by reference.

### U.S. GOVERNMENT RIGHTS

This invention was made with U.S. Government support under grant contract No. CMMI0624597 awarded by the National Science Foundation. The U.S. Government has certain rights in the invention.

### TECHNICAL FIELD

The field of the present disclosure relates to nanoscale patterning and manufacturing.

### BACKGROUND

Many upcoming applications, such as nanostructured biosensors and molecular electronics, utilize nanoscale structures such as nanochannels or nanowires. One challenge in nanostructure fabrication is to achieve both high resolution and high throughput at a low manufacturing cost. Currently, large-scale (e.g., wafer-scale) fabrication of sub-50 nanometer (nm) structures has yet to be demonstrated. The present inventors have recognized that development and commercialization of nanostructure-based devices far superior to the current devices are dependent upon the availability of low-cost manufacturing technologies for mass production of nanoscale patterns and structures.

Electron beam lithography has demonstrated 10 nm-resolution in patterning, but its serial processing nature impedes its usage in mass production. Other emerging techniques, such as focused ion beam or scanning probe lithography, have similar disadvantages. X-ray lithography has demonstrated the ability to pattern 20 nm-dimensions and below, but the mask material and resist systems need to be improved for high throughput. Other nontechnical issues associated with X-ray lithography are the high cost and lack of “granularity” of the X-ray source. Finally, nanoscale imprinting and other soft lithography methods are mainly dependent on physical contact of either a stamp or a mold having nanoscale features. Mold fabrication is another challenge associated with imprinting processes. Also, the contact pressure in these processes may lead to failure of the mold or the fabricated nanostructures, especially in wafer-scale patterning.

The shadow effect in high-vacuum evaporative deposition is a familiar topic, and its capability to fabricate sub-10 nm features has been previously demonstrated. (See, e.g., G. Philipp et al., “Shadow evaporation method for fabrication of sub-10 nm gaps between metal electrodes,” J. Microelectronic Engineering, v. 46, pp. 157-160 (1999)). Most work utilizes a shadow mask that is separated from the deposition substrate. The separated gap, however, may not be precisely maintained and the mask can be clogged during evaporation.

Pre-patterned nanoscale materials including nanotubes and nanospheres have also been used as a mask. (See J. Chung et al., “Nanoscale Gap Fabrication by Carbon Nanotube-Extracted Lithography (CEL),” Nano Letters, v. 3, pp. 1029-1031 (2003); and A. V. Whitney et al., “Sub-100 nm Triangular Nanopores Fabricated with the Reactive Ion Etching Variant of Nanosphere Lithography and Angle-Resolved Nanosphere Lithography,” Nano Letters, v. 4, pp. 1507-1511 (2004)).

The present inventors have recognized a need for improved nanoscale patterning and manufacturing.

### SUMMARY

Methods disclosed herein for forming zero- one- and two-dimensional nanogaps and nanostructures on a substrate entail high-vacuum oblique vapor deposition and a shadow effect of a pre-patterned layer. In some embodiments the pre-patterned layer is formed of metal deposited by evaporative deposition to achieve a layer having a precise thickness, which is then patterned to form a shadow mask. In one embodiment, patterning is performed by conventional photolithography and wet etch techniques known in the semiconductor industry. A second layer of material is then deposited obliquely to the surface by a directional deposition technique, such as evaporative deposition, so that the first layer casts a shadow over a portion of the substrate to form a nanogap over which the second layer is not deposited. A wafer-scale analytical model is proposed for predicting the width of nanoscale gaps fabricated by the shadow effect on pre-patterned edges. Sizes of nanogaps fabricated using the disclosed method may be on the order of 10 nm, e.g., from 20 nm to 60 nm, however, shadow edge lithography (SEL) methods according to the present disclosure have produced nanogaps as small as 3 nm.

Various nanostructures may be formed using nanogaps. Substrate material at the nanogap may be etched by a selective oxide etch to form a negative relief nanostructure, such as a nanochannel. Alternatively or in addition, the nanogap pattern may be reversed to form a positive relief nanostructure on top of the substrate by depositing in the nanogap a layer of material different from the first and second layers followed by a selective metal lift-off process for removing the first and second layers. To improve the yield of the lift-off process, an undercut may be created in the nanogap using either gas phase or wet etching. Also disclosed are methods of forming “zero-dimensional” structures such as nanodots, and two-dimensional structures, such as crossing nanowires and nanowire grids, by combining the compensation and pattern reversal techniques with multiple shadow patterning.

Furthermore, a method of compensating for cross-substrate variation of the oblique angle during deposition of the second material is disclosed. The compensation approach enables routine, low-cost fabrication of uniform features, that can be used to create nanogaps and nanostructures.

Nanostructures formed by the methods described herein may have usefulness in various fields, including nanofluidics, electronic circuits, nanoscale actuators, biosensors, and chemical sensors.

Additional aspects and advantages will be apparent from the following detailed description of preferred embodiments, which proceeds with reference to the accompanying drawings.

### BRIEF DESCRIPTION OF THE DRAWINGS

FIG. 1 is a schematic side sectional illustration of the formation of a nanogap using the shadow effect, according to an embodiment;

FIG. 2(a) is an illustration of the shadow effect of a pre-patterned edge in a high-vacuum deposition from a point source;

FIG. 2(b) is an illustration of the shadow effect of a pre-patterned edge in a high-vacuum deposition from a circular source;

FIG. 3(a) is another schematic side sectional illustration of nanogap formation during oblique deposition of an aluminum second layer over a pre-patterned aluminum first layer;

FIG. 3(b) is a schematic sectional elevation showing a configuration of an electron beam (e-beam) evaporation chamber showing two different positions and orientations of silicon wafers evaluated for deposition of the second layer (not drawn to scale);

FIG. 3(c) is a photograph of a 4-inch silicon wafer after deposition and patterning of an aluminum first layer;

FIG. 4 is a schematic side sectional illustration of an etch step of a patterning process used in a method of nanogap formation;

FIG. 5(a) is a top view SEM (scanning electron micrograph) image of a nanogap formed on the surface of a silicon wafer patterned with a 120 nm thick first aluminum layer, with magnified inset image;

FIG. 5(b) is a SEM image of a cross section of the nanogap of FIG. 5(a);

FIG. 6(a) is a top view SEM image of curved and tapered nanogaps formed at curved edges of a shadow mask first layer;

FIGS. 6(b) and 6(c) are magnified views of the curved nanogaps at inset regions 1 and 2 of FIG. 6(a), respectively.

FIG. 6(d) is a pictorial illustration of the formation of a crescent-shaped nanogap using a circular shadow mask;

FIGS. 7(a) and 7(b) are collections of is a top view SEM images of nanogaps on 180-p and 85-p silicon wafers, respectively, showing gap sizes at various distances from the center of the wafer

FIG. 7(c) is a diagram identifying the locations on the wafers of FIGS. 7(a) and 7(b) shown in the uppermost and lowermost images of FIGS. 7(a) and 7(b);

FIG. 8 is a graph showing shadow gap variation across 4-inch wafers, relating nanogap widths and their radial distance from the center of their respective wafers for three different thicknesses of shadow mask first layers deposited on both parallel (p) and tilted (t) wafers;

FIG. 9(a) is a schematic side elevation of the evaporation chamber set-up for nonconformal evaporative deposition of the first layer, which compensates for differences in the incident angle of deposition of the second layer across the width of the wafer;

FIG. 9(b) is a schematic bottom view of 4-inch silicon wafers of FIG. 9(a) loaded on a horizontal deposition plane;

FIG. 9(c) is a schematic side elevation of the evaporation chamber set-up for evaporative deposition of the second layer, utilizing a compensating mask formed in the first layer of FIG. 9(a);

FIG. 9(d) is a schematic bottom view of 4-inch silicon wafers of FIG. 9(c) when loaded on tilted deposition planes;

FIG. 10(a) is a diagram showing the positions of horizontal nanogaps patterned on a 4-inch silicon wafer.

FIG. 10(b) is a set of top view SEM images of five uncompensated nanogaps formed on a silicon wafer in the locations shown in FIG. 10(a);

FIGS. 10(c) and 10(d) are top view SEM images of nanogaps of two different nominal widths formed at the locations on the wafer illustrated in FIG. 10(a) using a compensation technique so as to result in more uniform gap widths across the wafer;

FIG. 11(a) is a graph of nanogap widths, as a function of x-position on a 4-inch silicon wafer, wherein the x-axis is indicated in FIG. 9(b);

FIG. 11(b) is a graph of nanogap widths as a function of y-position on a 4-inch silicon wafer, wherein the y-axis is indicated in FIG. 9(b);

FIG. 12(a) is a top view SEM image of an array of Cr nanowires formed by reversing nanogaps similar to those shown in FIGS. 10(c) and 10(d);

FIG. 12(b) is a pictorial SEM image of one of the Cr nanowires shown in FIG. 7(a); the inset shows an optical microscope image at lower magnification;

FIGS. 13(a) to 13(f) are cross-sectional views showing a sequence of steps in a method of polysilicon nanowire fabrication;

FIGS. 14(a) and 14(b) are top view SEM images of an array of polysilicon nanowires at respective low and high magnification, wherein the inset in FIG. 14(b) shows an enlarged perspective section view of a representative polysilicon nanowire;

FIGS. 15(a) to 15(i) are cross-sectional views showing a sequence of steps in a method of nanochannel fabrication;

FIG. 16(a) is a photomicrograph showing a top view of nanochannels fabricated on the surface of a substrate using a 180-t first layer mask;

FIG. 16(b) is a perspective SEM image of the nanochannels of FIG. 16(a);

FIG. 16(c) is an enlargement of a region of the SEM image of FIG. 16(b) showing a side section of one of the nanochannels;

FIGS. 17(a) and 17(b) are photographs showing the results of diffusion experiments testing the nanochannels of FIGS. 16(a) to 16(c), with FIG. 17(a) showing λ-DNA molecules treated with PICO-GREEN® intercalating dye having uniform fluorescence intensity and FIG. 17(b) showing λ-DNA molecules treated with fluorescein only and exhibiting gradually decreasing fluorescence intensity;

FIG. 18 is a pictorial illustration showing crossing layers of shadow mask material for formation of a nanodot or nanowell utilizing oblique deposition;

FIGS. 19(a) to 19(d) are pictorial illustrations showing a sequence of processing steps used to fabricate a two-dimensional array of square nanodots;

FIG. 20(a) is a pictorial diagram showing the shadow effect of a pre-patterned mask layer and geometric compensation using mask edges of varying thickness.

FIG. 20(b) is a pictorial illustration showing nanogaps with uniform width to be used as basic nanoscale patterns for fabrication of nanostructures;

FIG. 20(c) is a pictorial illustration of nanowires fabricated from the nanogaps of FIG. 20(b) by pattern reversal;

FIG. 20(d) is a pictorial illustration of a composite mask for forming an array of nanowells in or nanodots on a substrate by a double shadow edge lithography technique;

FIG. 20(e) is a pictorial illustration of a grid of crossing nanowires fabricated by double shadow evaporation;

FIGS. 21(a) to 21(c) are SEM images of zero-, one-, and two-dimensional nanostructures formed by methods disclosed herein;

FIG. 22 is a graph comparing the edge roughness of a patterned first aluminum layer used as a shadow edge, a second aluminum layer deposited at a rate of 10 Å/s (1 nm/sec), and a second aluminum layer deposited at a rate of 1 Å/s;

FIG. 23(a) is a top view SEM image of a rough-edged 49 nm nanochannel formed by depositing the aluminum second layer at a rate of 10 Å/s; and

FIG. 23(b) is a top view SEM image of a smooth-edged 65 nm nanochannel formed by depositing the aluminum second layer at a rate of 1 Å/s.

### DETAILED DESCRIPTION OF PREFERRED EMBODIMENTS

### Nanogap Formation

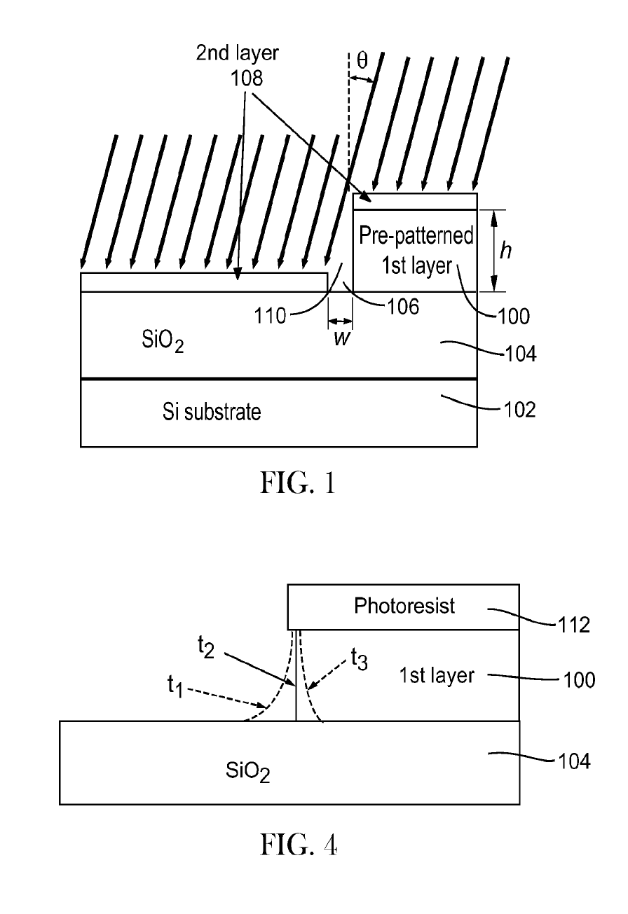

In one embodiment, the shadowing effect is utilized to fabricate nanostructures on a silicon (Si) wafer substrate. FIG. 1 provides an overview of the shadowing effect in accordance with an embodiment of a method referred to herein as shadow edge lithography (SEL) for convenience, it being understood that the methods described herein are distinguishable from conventional lithography techniques. With reference to FIG. 1, a first layer 100 of material is deposited and patterned on the surface of a Si wafer substrate 102, on which a surface oxide layer 104 (SiO₂) has been grown. In the embodiment illustrated, patterning first layer 100 creates a “pre-patterned layer” having a height h above the oxide surface and a region of bare SiO₂ 106 adjacent to the pre-patterned regions. Patterning may be performed using conventional photoresist lithography and etch techniques, leaving relatively large patterns and large bare regions. Next, a second layer 108 of material is deposited by a directional deposition method, such as evaporative vapor deposition. During deposition of the second layer, the relative positions of the substrate and the evaporation source and the relative angle of the substrate surface to the line-of-sight path from the evaporation source to the substrate are selected to achieve an oblique deposition angle, θ. As described in further detail herein, a highly directional deposition technique such as evaporative deposition is used so that pre-patterned first layer 100 casts a shadow over a region of bare SiO₂ 106. Second layer 108 is not deposited in the shadowed region, leaving a nanogap 110 having a width w determined by the thickness h of pre-patterned first layer 100 and the incident angle θ of oblique deposition of second layer 108, as set forth in Eq. (i):

w=h tan θ (i)

Embodiments of SEL methods described herein are proposed for formation of nanogaps 110 having widths w in ranging from approximately 2 nm to approximately 100 nm. In some embodiments, pre-patterned first layer 100 and second layer 108 may be formed of the same material, such as aluminum (Al) that is deposited by a directional deposition technique, such as e-beam evaporative deposition. In other embodiments, first and second layers 100 and 108 may be formed of different materials, such as two different metals. Forming first and second layers 100 and 108 of the same material may facilitate etching or lift-off of first and second layers 100 and 108 in a single process step following the formation of other nanostructures, as further described herein.

### Analytical Model for SEL

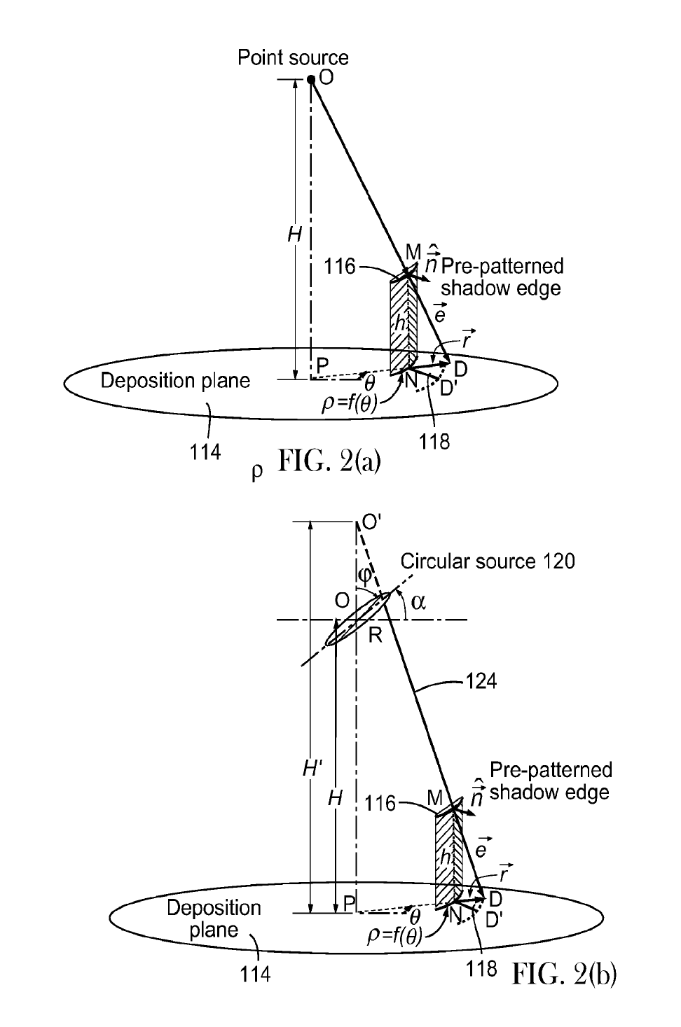

To fully implement the shadow effect for mass production, an analytical model is needed, especially for a relatively large geometric scale. To address these issues, an analytical model is disclosed herein for predicting the width w of nanogaps 110 fabricated by the shadow effect of pre-patterned layers on a substrate (see FIGS. 2(a) and 2(b)). The theoretical results are compared with experimental results from 4-inch Si wafers to evaluate the precision of the proposed method.

In high-vacuum deposition, the material to be deposited is either evaporated or sublimed by resistive heat or a high-energy electron beam. Because the quantum mechanical wavelength of evaporating molecules is usually extremely small (for an aluminum atom, the wavelength can be less than 1 Å), the diffraction effect in evaporation is negligible. As a result, the ultimate resolution of the SEL method is not limited by the wave diffraction of the evaporating molecules. Rather, the resolution of SEL is limited by the adhesion, hopping, and diffusion of the deposition material during the oblique shadowed deposition step, which contribute to roughness of the shadow edges and, in turn, roughness of the nanogaps.

When the vacuum pressure is lower than 0.1 mTorr, the mean free path of an evaporating molecule can be greater than the distance between the evaporation source and deposition substrate. In this circumstance, the trajectory of an evaporating molecule can be assumed to be a straight line from the source to the substrate and the geometric distributions of the shadow effect can be derived based on a “line-of-sight” assumption. Although the line-of-sight assumption is usually true for high-vacuum evaporative deposition, deposition paths, in reality, are not parallel due to the finite values of characteristic dimensions, such as the diameter of evaporating source, the diameter of the deposition substrate, and the distance between the evaporating source and the substrate. As a result, the distributions of the shadowing effect may vary geometrically. Geometric distributions have been found to affect the quality and uniformity of nanostructure fabrication. The inventors have determined that nanoscale features and nanostructures created by SEL on a 4-inch wafer can vary in size by as much as ±10 nm or more across the wafer (i.e., as much as 100% of the nominal feature size or more).

With reference to FIG. 2(a), in the simplest case, deposition molecules evaporate from a point source O at height H from a deposition plane 114. In polar coordinates (ρ, θ, and φ), a shadow edge 116 having a uniform height h above deposition plane 114 can be expressed by

ρ=ƒ(θ) (1)

Expressed in corresponding Cartesian coordinates, Eq. (1) becomes

x=ƒ(θ)cos θ (2a)

y=ƒ(θ)sin θ (2b)

The width w of a shadow gap 118 can be expressed by

w=\vec{e}·{right arrow over (\hat{n}=\vec{r}·{right arrow over (\hat{n} (3)

where vector \vec{e} is defined by \vec{MD} (M and D are the crossing points of the evaporating beam on shadow edge 116 and on deposition plane 114, respectively), \vec{r} is the projection of \vec{e} onto deposition plane 114, and {right arrow over (\hat{n} is a unit vector at point M defining the local direction of shadow edge 116. Note that a shadow exists only if w>0, i.e., the angle between \vec{r} and {right arrow over (\hat{n} is smaller than 90°. Expressed in corresponding Cartesian coordinates,

$${n}^{\hat{\to }} = [ \frac{- d y / d x}{\sqrt{( 1 + {( d y / d x )}^{2}}} , \frac{1}{\sqrt{( 1 + {( d y / d x )}^{2}}} ] , \qquad ( 4 )$$

while in polar coordinates,

$$\vec{r} = \frac{h}{H} ρ {r}^{\hat{\to }} = \frac{h}{H} f ( θ ) ( cos θ , sin θ ) \qquad ( 5 )$$

### Thus,

$$w = \vec{r} \cdot {n}^{\hat{\to }} = \frac{h}{H} \frac{f ( θ )}{\sqrt{1 + {[ {f}^{′} ( θ ) / f ( θ ) ]}^{2}}} \qquad ( 6 )$$

where h<<H for nanoscale structures.

In reality, material is always evaporated from an area rather than from a point as shown in FIG. 2(b). For a circular source 120 having a radius R and a deposition height H, if the circular source 120 is tilted by an angle α with respect to deposition plane 114, the actual width of shadow gap 118 is determined by a beam of evaporated material 122 that originates from the outermost point along the circumference of circular source 120 and travels along a beam path 124 to a point M in shadow edge 116, beam path 124 extending to a virtual point O′ where the path intersects the extended axis of OP. In this way, it can be assumed that the beam is evaporated from a “virtual” point source O′ at a deposition height

$${H}^{′} = \frac{H + R cos ϕ}{f ( θ ) - R sin ϕ} f ( θ ) \qquad ( 7 )$$

where φ is determined by

$$tan ϕ = \frac{cot α}{cos θ} \qquad ( 8 )$$

Substituting H′ for the zenith angle in spherical coordinates having an original point O in Eq. (6)

$$w = \frac{h}{H + R cos ϕ} \frac{f ( θ ) - R sin ϕ}{\sqrt{1 + {[ {f}^{′} ( θ ) / f ( θ ) ]}^{2}}} \qquad ( 9 )$$

describes the shadow width associated with an arbitrary shadow edge 116 having a uniform height h.

As a specific example, a shadow edge 116 in the shape of an arc of a circle with center point P can be expressed as

ρ=ρ₀ (10)

where ρ₀ is the radius of the circle. Inserting Eq. (10) into Eq. (9) results in

$$w = \frac{{ρ}_{0} - R sin ϕ}{H + R cos ϕ} h \qquad ( 11 )$$

For a circular source 120 parallel to deposition plane 114, α is 0° and φ is 90° regardless of θ. Therefore Eq. (11) is reduced to

$$w = \frac{{ρ}_{0} - R}{H} h \qquad ( 12 )$$

According to Eq. (12), a shadow edge 116 within a radius R from the center of deposition plane 114 does not cast a shadow.

On the other hand, a straight edge at a position ρ₀ relative to center point P, expressed as

$$ρ = \frac{{ρ}_{0}}{cos θ} , \qquad ( 13 )$$

has a shadow width given by

$$\begin{matrix}w = \frac{{ρ}_{0} - R sin ϕ cos θ}{H + R cos ϕ} h \\ or & ( 14 ) \\ w = \frac{{ρ}_{0} - R cos θ}{H} h & ( 15 )\end{matrix}$$

for the tilted and parallel cases, respectively. Equations (13), (14), and (15) reduce to Equations (10), (11) and (12), respectively, as θ→0. In this case, we can use the shadow width of a corresponding circular edge to approximate that of a straight edge.

Shadow widths formed by shadow edges 116 of different shapes casting shadows on deposition plane 114 are summarized in Table 1 for point sources and circular sources.

TABLE 1
Shadow widths of pre-patterned edges of different shapes.

| Shadow edge | Sources (with a radius R and a deposition height H) | | |
|---|---|---|---|
| shapes (with a | Circular source | Circular source | Point source |
| uniform height h) | (tilted case) | (parallel case) | (R = 0) |
| Arbitrary shape: ρ = f(θ) | $\begin{matrix}w = \frac{h}{H + R cos ϕ} \frac{f ( θ ) - R sin ϕ}{\sqrt{1 + {[ {f}^{′} ( θ ) / f ( θ ) ]}^{2}}} \\ ( where tan ϕ = cot α / cos θ )\end{matrix}$ | $w = \frac{h}{H} \frac{f ( θ ) - R }{\sqrt{1 + {[ {f}^{′} ( θ ) / f ( θ ) ]}^{2}}}$ | $w = \frac{h}{H} \frac{f ( θ )}{\sqrt{1 + {[ {f}^{′} ( θ ) / f ( θ ) ]}^{2}}}$ |
| Straight line: $ρ = \frac{{ρ}_{0}}{cos θ}$ | $w = \frac{{ρ}_{0} - R sin ϕ cos θ}{H + R cos ϕ} h$ | $w = \frac{{ρ}_{0} - R cos θ}{H} h$ | $w = \frac{{ρ}_{0}}{H} h$ |
| Center circle: ρ = ρ₀ | $w = \frac{{ρ}_{0} - R sin ϕ}{H + R cos ϕ} h$ | $w = \frac{{ρ}_{0} - R }{H} h$ | $w = \frac{{ρ}_{0}}{H} h$ |

### Experimental Results

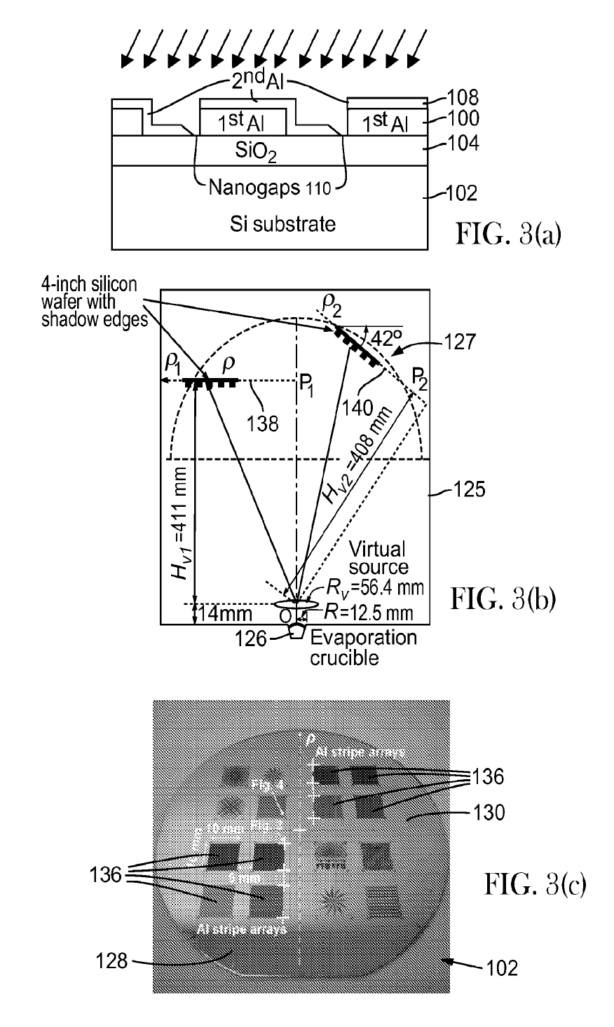

The following experimental processing steps were performed to create nanogap arrays on Si wafers using SEL as shown in FIGS. 3(a), 3(b), and 3(c). First, 4-inch p-type Si wafers with <100> crystal orientation corresponding to substrates 102 were thermally oxidized at 1100° C. to grow a 300 nm thick oxide layer 104. Then an electron-beam (e-beam) evaporation chamber 125 (NRC 3117, Varian Inc., Palo Alto, Calif.), diagrammed in FIG. 3(b), was used to deposit a thin film of aluminum (Al) on the oxidized Si wafers, the Al thin film corresponding to first layer 100. An evaporation source comprising a circular evaporation crucible 126 of radius 12.5 mm was located at the bottom of evaporation chamber 125 and Si wafers were loaded into a rotatable planetary system 127 at the top of evaporation chamber 125. After loading Si substrates 102 and Al source 126, a 3 μTorr vacuum was created in chamber 125, and the filament voltage for electron emission was set in to 7 kV. Subsequently, the current was gradually increased to heat Al source 126. After a 60 sec soaking time to remove impurities in the molten Al, the current was controlled for a constant deposition rate of 10 Å/s. At this deposition rate, the vacuum pressure was maintained to be lower than 50 μTorr. In the vacuum, the mean free path of Al atoms is larger than 1 meter so that the “line-of-sight” assumption holds. In-situ control of deposition thickness was maintained by a crystal monitor (Inficon XTC controller) throughout the evaporation process.

In one set of experiments, planetary system 127 in e-beam chamber 125 was rotated during deposition of Al first layer 100 to achieve conformal deposition, such that Al layers of uniform thickness were deposited on the oxide layer. Several batches of samples were created, including first Al layers of thickness 85 nm, 120 nm and 180 nm. Then, photoresist was spin-coated and patterned on the Al layers by conventional ultraviolet (UV) photolithography. Using a photoresist mask, Al first layers 100 were isotropically etched to form various patterns as shown in FIG. 3(c). Si substrate 102 was divided into four zones. Left-bottom zone 128 and right-top zone 130 contain arrays of horizontal, straight Al stripes. All arrays are located within 10 mm by 10 mm square areas 136. Square areas 136 are separated from each other by 5 mm such that their positions can be conveniently identified. Due to their small sizes, the Al stripes cannot be seen in the image of FIG. 3(c).

During patterning of first layer 100, isotropic etching of first layer 100 may be controlled to achieve a desired profile shape of the etched sidewall of first layer 100, as illustrated in FIG. 4. With reference to FIG. 4, after exposure of a photoresist 112, first layer 100 is preferably isotropically etched using a wet etchant, such as hydrochloric acid. Because photoresist 112 is hydrophobic and SiO₂ layer 104 is hydrophilic, the wet etchant can be applied to etch first layer 100 faster toward substrate 102 and slower near photoresist 112. The hydrophobic and hydrophilic nature of the respective photoresist and oxide layers enables the shape of the edge of first layer 100 to be controlled as follows: at time t₁ the etchant begins to reveal underlying surface oxide layer 104. Thereafter, the etching process may be continued until the edge of first layer 100 is substantially perpendicular to the substrate surface, forming a step at time t₂. If the etch process is allowed to continue, eventually first layer 100 will be undercut at time t₃, wherein t₁<t₂<t₃. Desirably, the etch time is targeted to achieve a relatively sharp step, as at t₂. Alternatively, the etch time may be targeted to achieve a slightly undercut step, as at t₃, to inhibit adhesion to the sidewall of first layer 100 of a nanostructure material deposited adjacent first layer 100 and to facilitate subsequent lift-off of first layer 100. After patterning of first layer 100, photoresist 112 is removed by any suitable manner, such as a photoresist stripper chemical of the kind used in the field of semiconductor device manufacturing.

First layer 100, thus patterned, forms a shadow mask (i.e., a shadowing or shield) for subsequent deposition of Al second layer 108, which is deposited at oblique angle of incidence θ relative to the substrate surface using the same e-beam evaporative deposition equipment as was used for depositing Al first layer 100 (Varian NRC 3117). During experimental deposition of second layer 108, some wafers were positioned in the deposition chamber at an orientation parallel (p) to evaporation source 126, while others were tilted (t) relative to evaporation source 126, as illustrated in FIG. 3(b). The parallel (p) and tilted (t) wafers were positioned such that their ρ axes (La, ρ₁ and ρ₂ for the parallel and tilted cases, respectively) extended along corresponding deposition planes 138 and 140. In this way, the radial distances of shadow edges 116 from the center point of the corresponding deposition plane (i.e., P₁ and P₂ for the parallel and tilted case, respectively) could be conveniently determined. The distances were used to compute theoretical shadow widths using either Eq. (12) for the parallel wafers or Eq. (11) for the tilted wafers. Note that planetary system 127 was not rotated during the second deposition so that nanogaps 110 were created as illustrated in FIG. 3(a).

A total of six batches of wafers were prepared under different deposition conditions and were marked as 85-p, 120-p, 180-p, 85-t, 120-t, and 180-t. In these expressions, the numbers represent the Al thicknesses of 85, 120, and 180 nm during the first layer Al deposition; the suffixes -p and -t denote “parallel” or “tilted” during the second layer Al deposition.

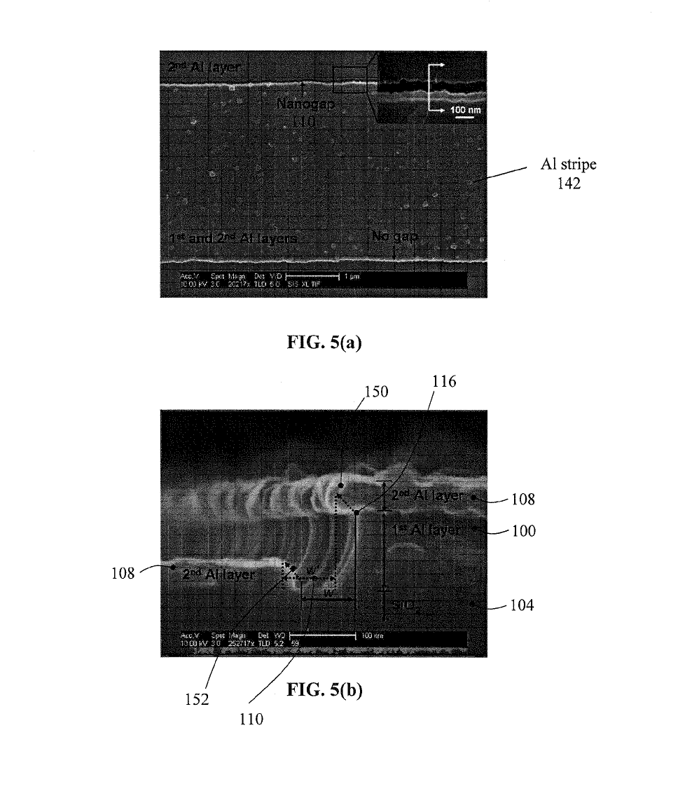

In some examples, after depositing first and second Al layers 100 and 108, a reactive ion etching (RIE; Trion RIE, CHF₃+O₂) step was performed to remove SiO₂ material at the nanogaps, using Al first and second layers 100 and 108 together as a mask to fabricate nanochannel arrays. The Al layers were then removed by a wet etch process and scanning electron microscopy (SEM; FEI Sirion) was used to image the specimens, as shown in FIGS. 5(a) and 5(b). FIG. 5(a) shows a straight nanogap 110 formed on a 120-t Si wafer. Nanogap 110 was created at the top edge of a pre-patterned Al stripe 142 where the angle between \vec{r} and {right arrow over (\hat{n} in FIG. 3(b) was smaller than 90°; while at the bottom edge of Al stripe 142, no nanogap was created because the angle exceeded 90°. Hence, experimental results were consistent with theoretical predictions. It was also interesting to find an “eave”-shaped structure (or cornice) 150 shown in FIG. 5(b), which was formed by Al second layer 108 at the edge of Al first layer 100 by adhesion of Al atoms as they passed close to the edge of Al first layer 100 during the oblique second deposition. The size of the overhanging cornice 150 may be reduced somewhat by reducing the deposition rate of the second Al layer. For example, a deposition rate of approximately 1 Å/sec will result in smaller particle size and a smaller overhanging cornice 150.

Formation of Al second layer 108 and cornice 150 causes the thickness and location of shadow edge 116 to change during deposition of Al second layer 108. The changing position of shadow edge 116 results in Al second layer 108 having a slanted profile 152 adjacent to the nanogap where the second Al layer is deposited on the surface of the SiO₂, as illustrated in FIGS. 3(a) and 5(b).

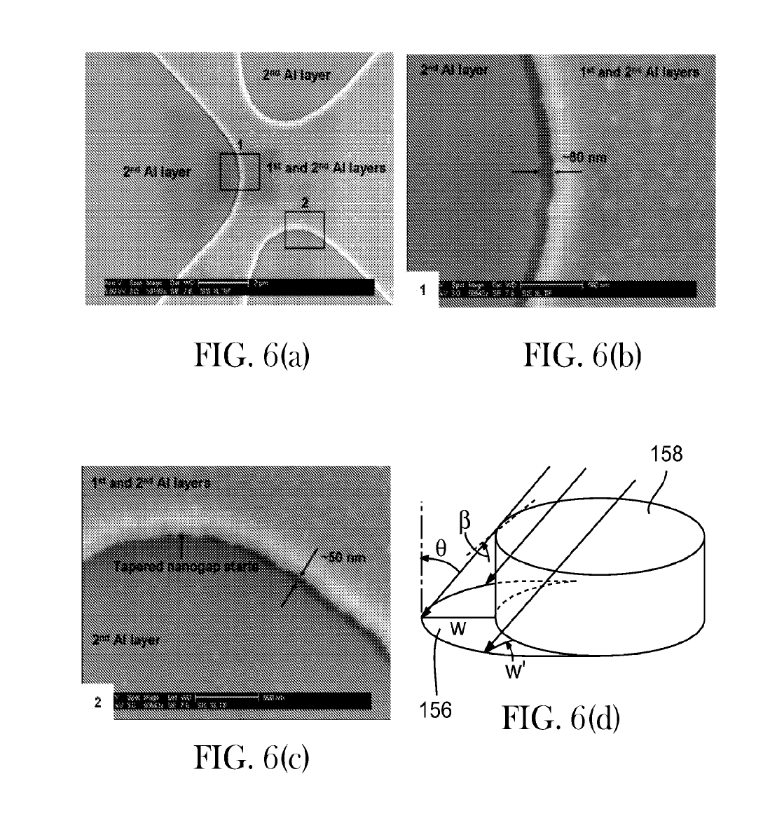

In other embodiments, first Al layer 100 may be patterned in curved shapes, i.e., with edges curved in the plane of substrate 102. FIGS. 6(a), 6(b), and 6(c) show the formation of curved nanogaps with tapered widths at curved edges of Al first layer 100 on a 180-t Si wafer at the position indicated in FIG. 6(c), where the angle between \vec{r} and {right arrow over (\hat{n} was smaller than 90°. FIGS. 6(a)-6(c) show the potential of tapered nanogaps 154 as a two-dimensional lithography technique. FIG. 6(d) illustrates formation of a crescent-shaped nanogap 156 using a pillbox-shaped structure 158 as a shadow edge.

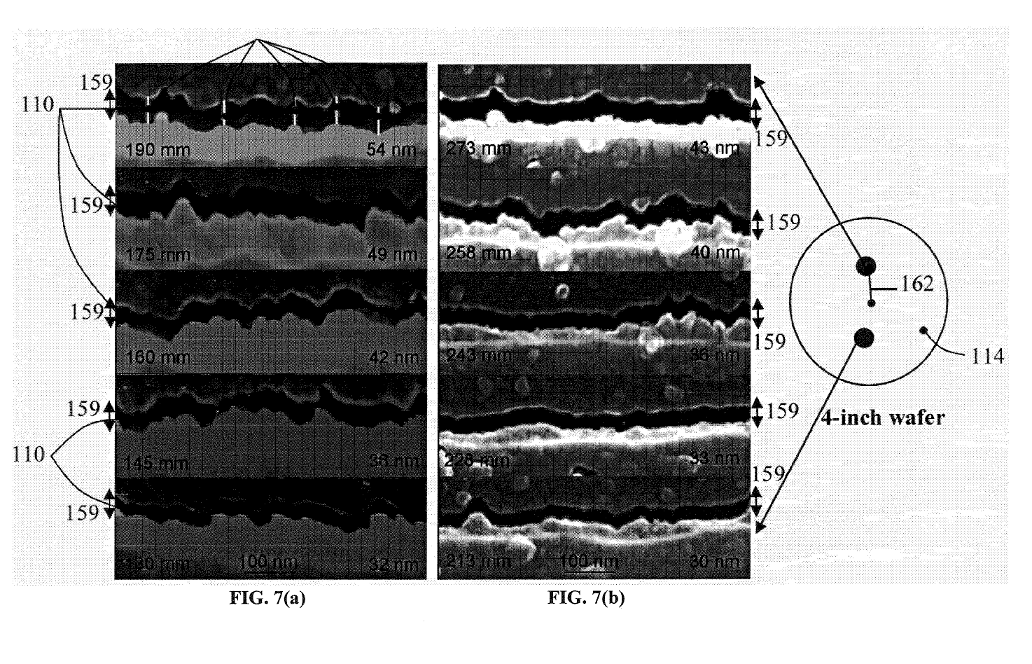

To evaluate geometrical distributions of the shadow effect at the wafer scale, FIGS. 7(a) and 7(b) show nanogaps 110 created by straight shadow edges at different locations on 180-p and 85-t wafers, respectively (as indicated by the white cross marks in FIG. 3(c)). Widths 159 of nanogaps 110 in FIGS. 7(a) and 7(b) were measured indirectly from top-view images because the shadow edge 116 of first Al layer 100 is obscured by overhanging cornice 150 shown in FIG. 5(b). Distance w′ between the end of the cornice 150 and the top edge of second Al layer 108 on the opposite side of nanogap 110 is approximately equal to the true width w of nanogap 110. Thus, nanogap widths can be inferred from top-view images.

To determine the average width 159 of a nanogap, five positions 160 were chosen along the length of the nanogap indicated by five bright lines shown in the top image in FIG. 7(a). At positions 160, tangents to the nanogap edge are aligned with the global direction of the nanogap. The radial position 162 of the nanogap on the corresponding deposition plane 114 for deposition of second Al layer 108 is indicated in the lower left corner of each image (e.g., 190 mm is the radial position 162 of the nanogap in the top image in FIG. 7(a)); the average width 159, w, of the nanogap is indicated at the lower right-hand corner of each image (e.g., 54 nm for the nanogap in the top image in FIG. 7(a)). FIGS. 7(a) and 7(b) clearly show that gap width 159 varies by about 15-20% with radial position 162 during the deposition of second Al layer 108.

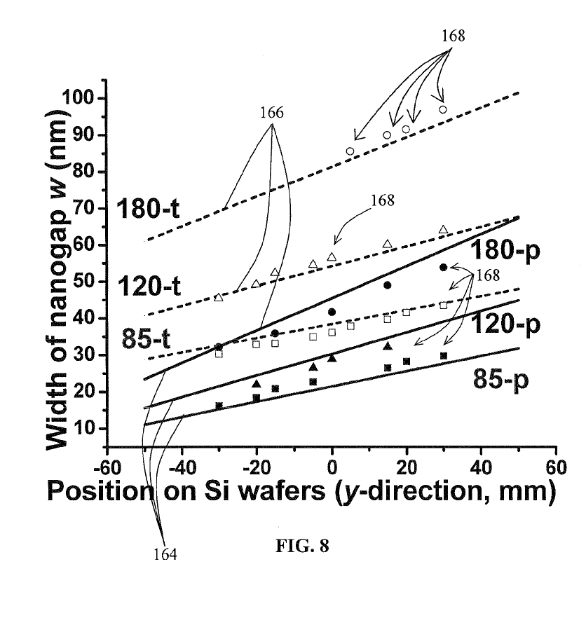

The relationships between nanogap widths 159 and corresponding radial positions 162 are plotted in FIG. 8 for both the parallel and tilted cases. To compare experimental results with theoretical prediction, evaporation source 126 is considered to be a virtual source characterized by a high-pressure viscous cloud of very hot evaporant. The cloud forms a larger perimeter than that of the actual evaporation source. Assuming that the virtual source has a circular area, experimental curves relating nanogap widths 159 to radial positions 162 can be linearly fitted as described in Eq. (12). Linear fit curves 164 for 85-p, 120-p, and 180-p wafers are then used to determine the position and radius of the virtual source. In this case, linear fit curves 164 indicate the virtual source was located at a height (Hᵥ) approximately 14 mm from the crucible surface with a radius (Rᵥ) of approximately 56.4 mm. Applying the dimensions to Eq. (11), theoretical curves 166 for the 85-t, 120-t, and 180-t wafers were plotted as the three dashed lines in FIG. 8. As shown in the graph, the experimental data indicated by points 168 along curves 164 and 166 agree well with the theoretical prediction. Experimental data 168 was consistently repeatable with a tolerance of 5 nm under the same evaporation conditions. By this method, arrays of nanogaps with widths as small as 15 nm were fabricated on 4-inch Si wafers.

According to Eqs. (14) and (15), the average nanogap width 159 produced by a straight shadow edge 116 varies along its length due to the variation of oblique angle of incidence θ. Variation across a 4-inch wafer is less than 2% under specific wafer-loading conditions. Since the variation is negligible, being within the uncertainty range of experimental data, Eqs. (11) and (12) may be used instead of Eqs. (14) and (15), respectively, as an excellent approximation for the nanogap width formed by straight Al stripes 142.

SEM images show that concave features as small as 3 nm in first Al layer 100 are transferred to the patterns of second Al layer 108. Thus, surface diffusion during oblique Al deposition is speculated to be smaller than the 3 nm feature size. This also suggests that the smallest nanoscale feature is limited by the roughness of pre-patterned Al shadow edges 116 rather than the shadow effect itself.

### Compensation

As illustrated in FIG. 8, the width of nanogaps (and nanostructures derived from the nanogaps) varies across a 4-inch wafer due to cross-wafer variation in the incident angle θ. Approximately 10-30 nm variation was observed in 4-inch wafers, depending on the thickness of the shadowing layer. To obtain a more uniform nanogap dimension on a wafer scale, a compensation method was developed. The compensation method begins with depositing Al first layer 100 so that its thickness, instead of being uniform, is tapered over the width of substrate 102. This is referred to as a “nonconformal” deposition because surface of Al first layer 100 does not follow the (generally flat) topography of the substrate. Patterning the blanket Al first layer 100 then produces shadow edges of varying heights across the wafer, each shadow edge casting a shadow of a different size, according to its height and the local oblique angle of incidence, θ, and the wafer position. By judiciously positioning substrate 102 with respect to evaporation source 126, variation in the oblique deposition angle may be compensated by the multi-level shadow edges produced by tapered first Al layer 100. Through use of this compensation method, which is described in detail below, very long nanowires having highly uniform width may be formed.

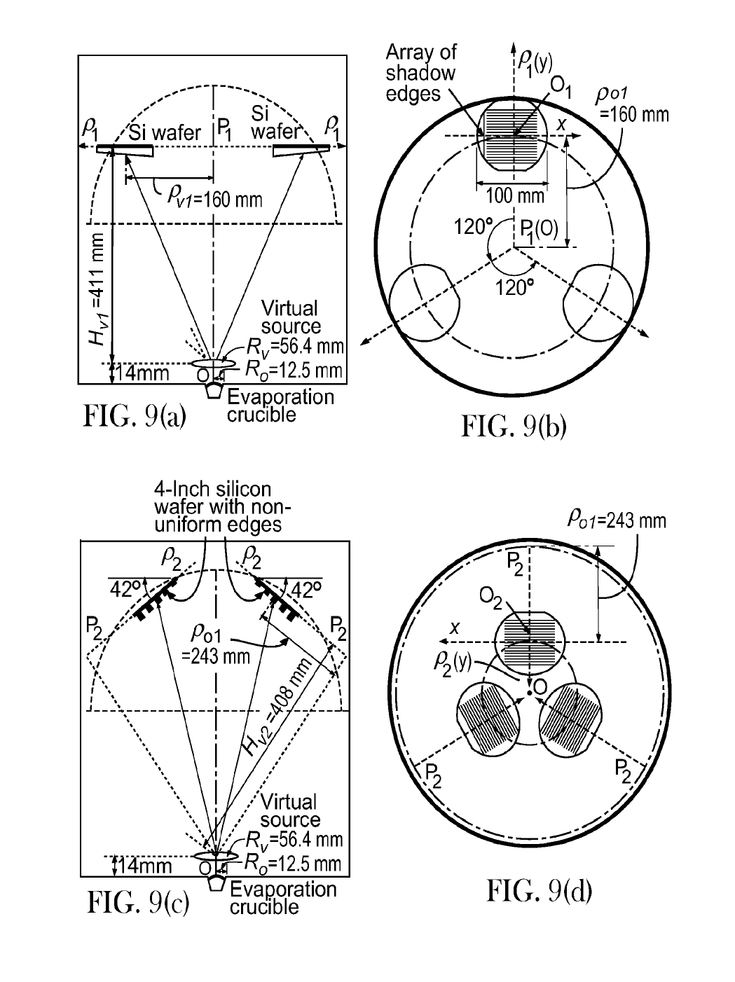

In a surface source of electron beam evaporation, atoms are ejected from a small planar area according to a cosine distribution to achieve a gradually varying Al height across the wafer. The wafer loading planetary is not rotated during evaporative deposition. The tapered film thickness distribution may be expressed as:

$$h / {h}_{0} = {[ 1 + {( \frac{ρ}{H} )}^{2} ]}^{- 2} \qquad ( 16 )$$

where h is film thickness at point (ρ, H) and h₀ is the thickness at point (0, H). Experimental results using an e-beam evaporation chamber (NRC 3117, Varian Inc., Palo Alto, Calif.), show that thickness profiles of first Al layer 100 agree well with Eq. (16). Subsequently, first Al layer 100 is patterned by conventional photolithography to create shadow edges. Then the wafer is positioned in the e-beam chamber again for the second Al evaporation. By adjusting the relative position and angle of the wafer during the second Al evaporation, the optimal compensation to achieve the desired nanogap width can be achieved for a 4-inch Si wafer. For example, the wafer may be rotated 180 degrees, to align the thinnest portion of first Al layer 100 closer to the source than the thickest portion. FIGS. 9(a) and 9(b) show the deposition chamber geometry for compensated first Al layer 100 deposition; FIGS. 9(c) and 9(d) show the deposition chamber geometry for compensated second Al layer 108 shadow edge deposition.

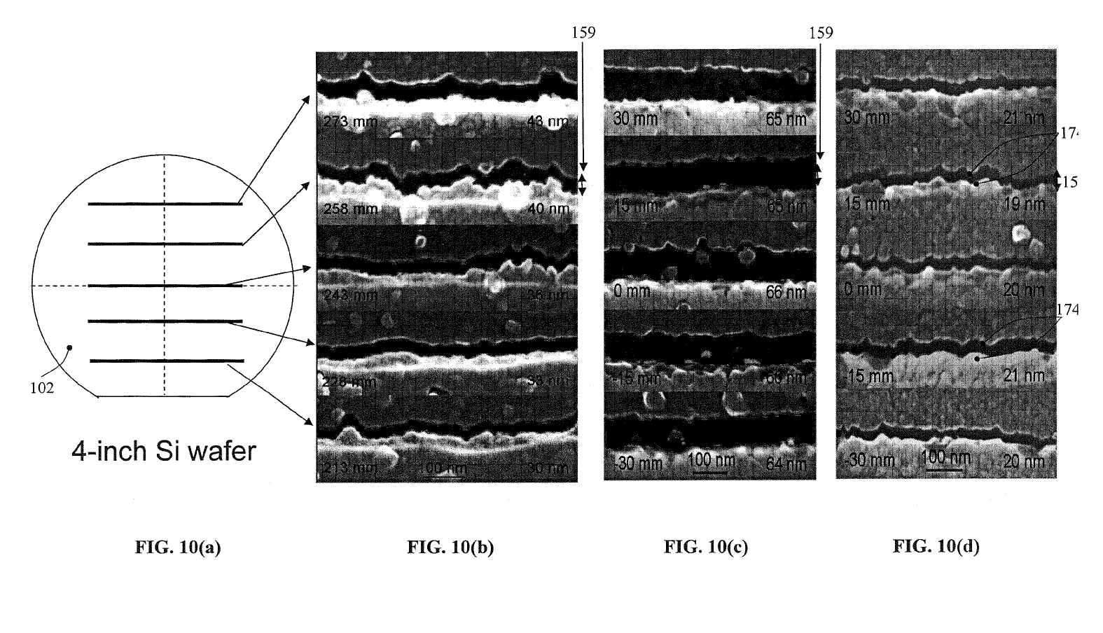

With reference to FIGS. 10(a)-10(d), nanogaps (shown as wavy black stripes in FIGS. 10(b)-10(d)) having widths 159 ranging from approximately 15 nm to 100 nm were successfully fabricated on 4-inch Si wafer substrates 102 using the compensation method. By adjusting the height of first Al layer 108 and incident deposition angle θ, gap width 159 may be uniformly fabricated with a tolerance of ±2 nm. FIG. 10(a) indicates the positions of 5 nanogaps on a 4-inch Si wafer. FIG. 7(b) is reproduced as FIG. 10(b) to show uncompensated nanogaps with a tolerance of about ±7 nm for comparison with the compensated nanogaps shown in FIGS. 10(c)-10(d). FIG. 10(c) illustrates the uniform gap width across a 4-inch wafer due to the compensation method. The fabricated nanogaps in FIG. 10(c) have widths of 66 nm±2 nm. FIG. 10(d) shows uniform 20 nm gaps with a similar tolerance of about ±2 nm. By this method, arrays of nanogaps having widths as small as 15 nm may be fabricated on 4-inch Si wafers. In FIGS. 10(b)-10(d) the radial position of each nanogap is indicated at the left bottom of each image; and its average width is indicated at the right-bottom of each image. In FIG. 10(b) the radial position of each nanogap is expressed relative to the central vertical axis of the deposition chamber, whereas in FIGS. 10(c) and 10(d), the radial position of each nanogap is expressed relative to the center of the wafer.

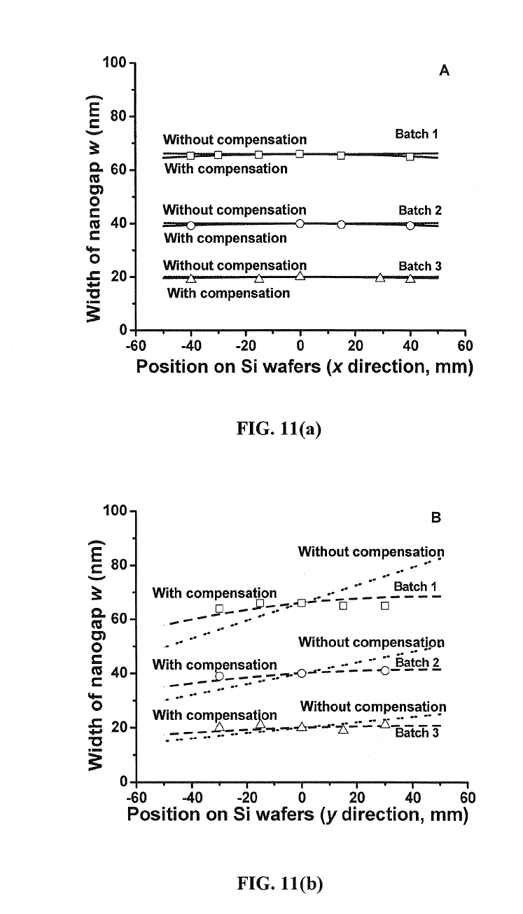

FIGS. 11(a) and 11(b) are graphs of nanogap widths as a function of their x-position and y-position, respectively, on a silicon wafer, wherein the x- and y-axes are indicated in FIG. 9(b). In FIG. 11(a) the discrete data points represent measurements and the solid curves represented predicted values, with and without compensation. In FIG. 11(b) the discrete data points represent measurements and the dashed curves represented predicted values, with and without compensation. FIG. 11(b) illustrates the dramatic effect of compensation as facilitating the fabrication of uniform nanostructures using wafer-scale SEL.

### Nanowires

Nanogaps 110 can also be used to fabricate nanowires by depositing a layer of a nanowire material different from the first and second layers, such as a different metal or a semiconductor material, followed by a lift-off process that removes first and second layers 100 and 108 and overlying portions of the nanowire material, leaving only the nanowire material at nanogap 110. Al second layer 108 is preferably deposited to a minimum thickness of approximately 5 nm for forming nanochannels and approximately 10 nm for forming nanowires, but may be deposited to a much greater thickness. Metal nanostructures can later be used as templates to create high-aspect ratio nanostructures including nanoholes, vertical wires, and nanowalls.

To improve the yield of the lift-off process, undercut sidewalls may be created at the nanogaps 110 using either gas phase or wet etching before deposition of the nanowire material. The undercut sidewalls may prevent adhesion of the nanowire material to the sidewalls of the first and second layers bordering the nanogap. In one embodiment, undercut sidewalls may be formed in the first layer during patterning of the shadow mask, as described above with reference to FIG. 4.

A pattern of nanogaps 110 similar to FIG. 7(c) may be reversed by depositing an additional chromium (Cr) layer 168 (or, alternatively, a Gold (Au) layer) to create nanowires. The Cr patterns can then be used as a mask for subsequent reactive ion etching (RIE), for fabricating semiconducting nanowires made of semiconducting materials such as Si, GaAs and InAs. To fabricate arrays of metal nanowires, or two-dimensional nanoscale electrodes, a Cr layer about 15 nm thick is deposited to fill in nanogap 110. In the process, the height difference between two layers can be decreased by depositing a thinner first Al layer 100 at, which will result in a smaller gap at step (i). Subsequently, the Al layers are removed in an etchant that is selective to Al, which also lifts off the portions of Cr layer 168 situated on top of the Al layers, while leaving intact the portions of Cr layer 168 defined in the nanogap positions. A thin layer of Cr (or Au) is also typically porous to the etchant used to dissolve the Al layers, thereby facilitating lift-off. The resulting patterns are Cr nanowires 169 as shown in FIGS. 12(a) (top view) and 12(b) (end view).

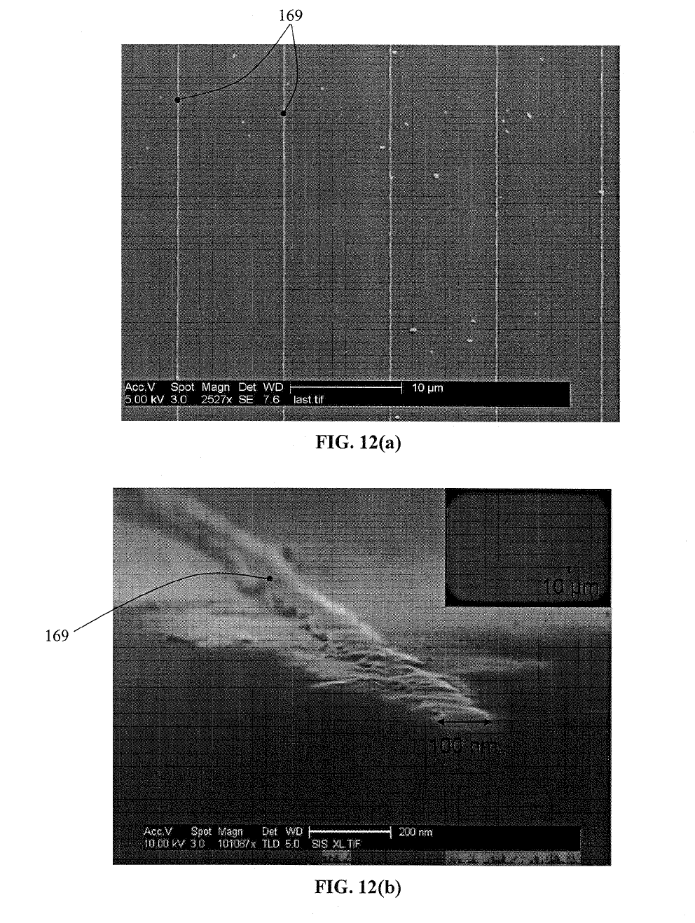

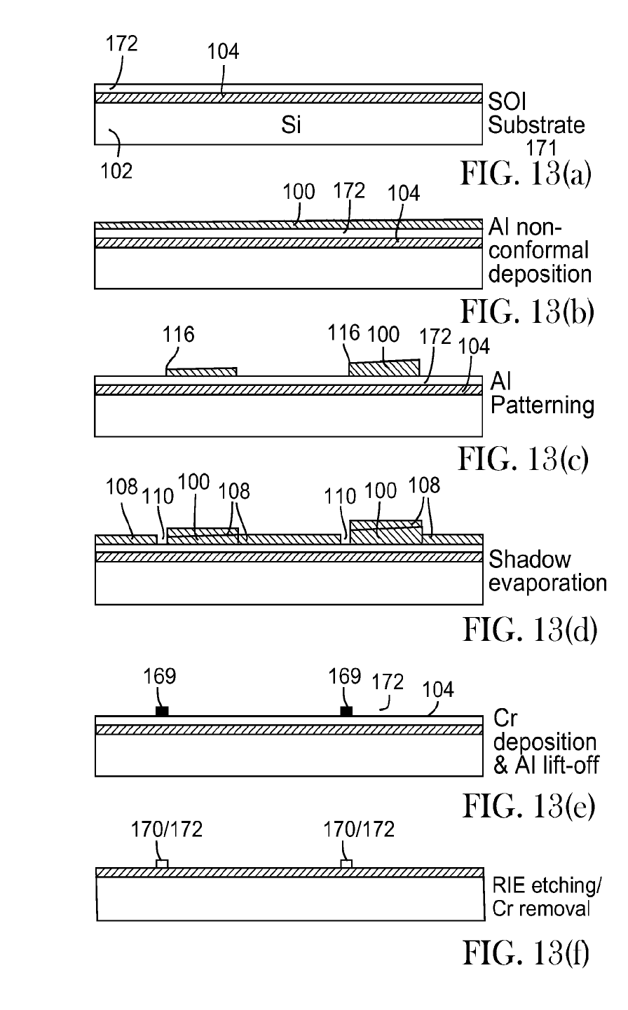

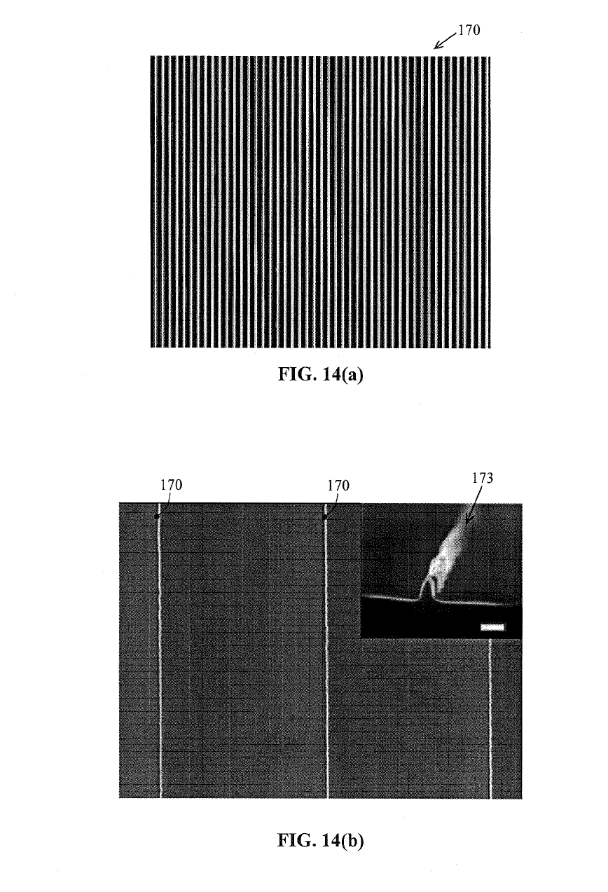

As an alternative to metallic wires, two kinds of Si nanowires may be fabricated: single crystal Si nanowires 170 on SOI (silicon on insulator) substrates 171 and poly-crystalline Si (polysilicon) nanowires on Si wafer substrates 102. A fabrication procedure for single crystal Si nanowires 170 with compensation is illustrated in FIGS. 13(a)-13(e). An SOI wafer 171 is prepared by depositing silicon 172 on surface oxide layer 104 (FIG. 13(a)). First Al layer 100 is evaporated at a fixed incident angle such that first Al layer 100 is non-conformally deposited on the wafer by evaporative deposition, so as to produce a layer with a tapered thickness (FIG. 13(b)). The incident angle θ is measured at the center of the wafer. The thickness of Al first layer 100 at the center of the Si wafer is 280 nm in order to create gap sizes of 100 nm, but the thickness increases from the center toward the source and decreases from the center in the direction away from the source. First Al layer 100 is patterned by a conventional lithography technique, leaving Al patterns and shadow edges 116 having different heights, as illustrated in FIG. 13(c). Second Al layer 108 is then deposited obliquely to create nanogaps 110 having a uniform gap width of 100 nm, as illustrated in FIG. 8(d). Subsequently a 10 nm-thick Cr layer 168 is evaporated onto the entire wafer. By removing first and second Al layers 100 and 108 in an Al etchant, the Al and the overlying Cr material are lifted off together, leaving Cr nanowires 169 on SOI substrate 171 in place of nanogaps 110, as illustrated in FIG. 8(e). Cr nanowires are used as a masking layer for reactive ion etching (RIE: Trion, CHF₃+O₂) to define Si nanowires 170 on SOI wafer. Fabrication of Si nanowires 170 across a 4-inch SOI wafer is completed by the removal of Cr layer 168 in an etchant. Note that the width of Si nanowires 170 can be reduced to 2 nm by adjusting incident angle θ and the height of first Al layer 100. Top view SEM images of finished Si nanowires 170 at two different magnifications are shown in FIGS. 14(a) and 14(b). The insert inset in FIG. 14(b) shows the corresponding cross-sectional view of the Si nanowire profile 173.

Polysilicon nanowires may be fabricated on a conventional Si wafer. First, the Si wafer is oxidized to grow a 500 nm-thick oxide layer. A 100 nm-thick polysilicon layer 174 is then grown by a low pressure chemical vapor deposition (LPCVD) method. After the polysilicon film growth, the rest of the fabrication steps are the same as the SOI wafer process shown in FIGS. 13(b)-13(f).

### Nanochannels

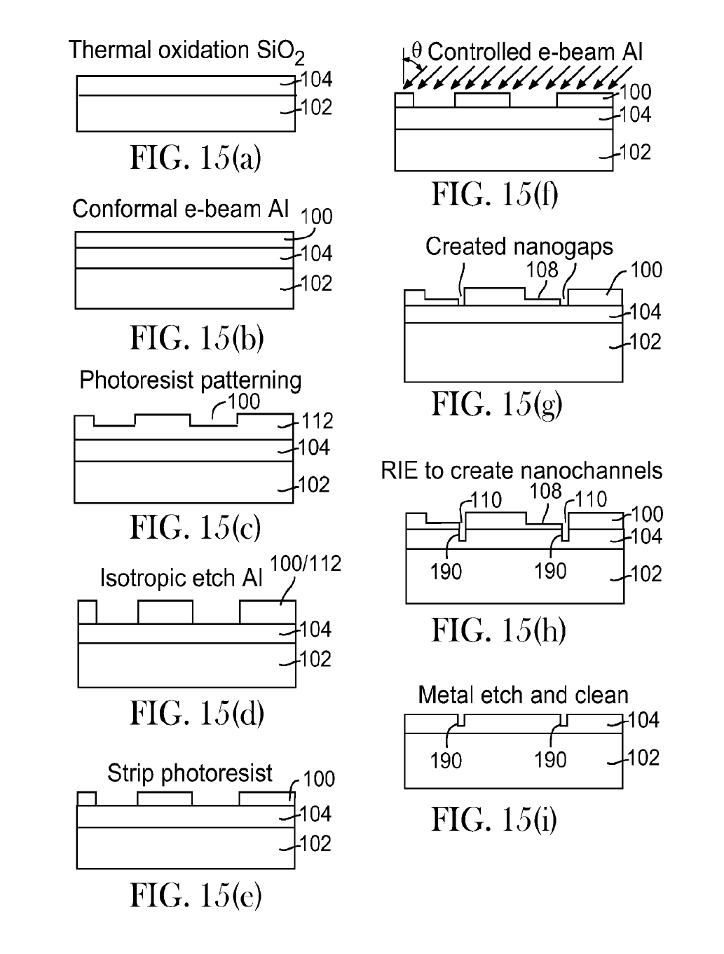

Nanogap 110 can be used to fabricate a nanochannel 190 by etching the bare SiO₂106. FIGS. 15(a)-15(i) illustrate a sequence of fabrication steps according to an embodiment of the method for forming nanochannels 190. Si substrate 102 is thermally oxidized to grow SiO₂ layer 104 (FIG. 15(a)). Then first Al layer 100 is evaporated onto SiO₂ layer 104 (FIG. 10(b)), followed by patterning of photoresist 112 (FIG. 15(c)). Then first Al layer 100 is etched using the photoresist 112 as a mask (FIG. 15(d)) and photoresist 112 is stripped in acetone (FIG. 15(e)). An array of nanogaps 110 is created by shadow edge deposition of second Al layer 108 on the pre-patterned first Al layer 100 (FIGS. 15(f) and 15(g)). At step FIG. 15(f), the angles between substrate 102 and evaporation source 126 are carefully adjusted for desired nanomanufacturing features. To create nanochannels 190, reactive ion etch (RIE) of bare SiO₂ layer 104 is performed by using first and Al layers 100 and 108 as a mask (FIG. 15(h)). After the RIE step, first and second Al layers 100 and 108 are removed by etching to achieve an array of nanochannels 190 (FIG. 15(i)).

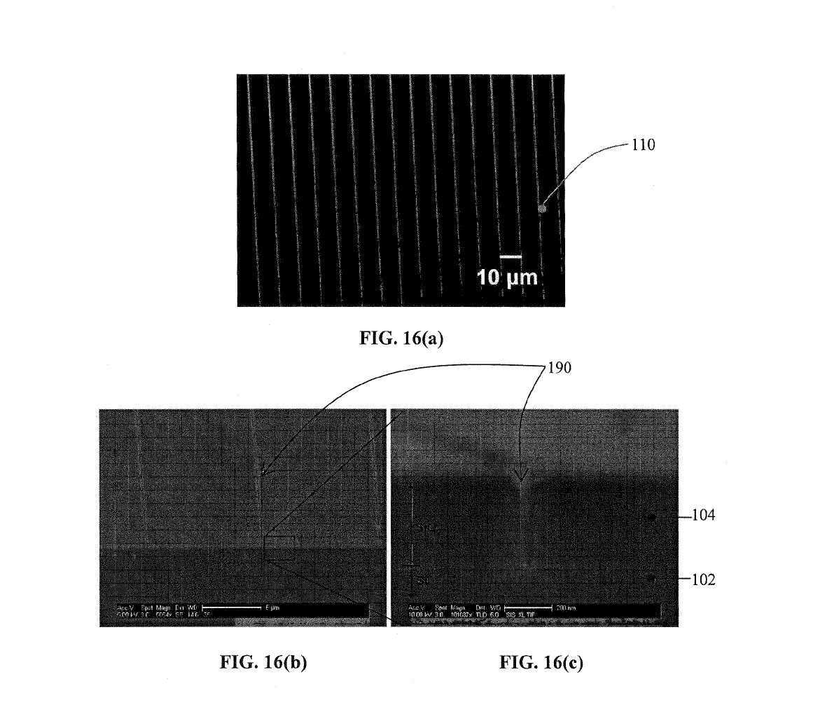

The present inventors have successfully fabricated nanogaps 110 and nanochannels 190 ranging from 15 nm to 100 nm on 4-inch Si wafers with ±3 nm resolution, as illustrated in the photomicrographs of FIGS. 16(a), 16(b), and 16(c). FIG. 16(a) shows an array of nanochannels 190 after reactive ion etch and the removal of Al layers 100 and 108 on a 180-t wafer. FIGS. 16(b) and 16(c) show SEM images of sectioned nanochannels 190 indicating the transfer of the nanogap patterns by reactive ion etch. The result demonstrates that deposited Al layers 100 and 108 can be used as a reactive ion etch mask to transfer nanoscale patterns. Note that the 10 μm spacing in the array is limited by the patterning of first Al layer 100, not by the shadow effect.

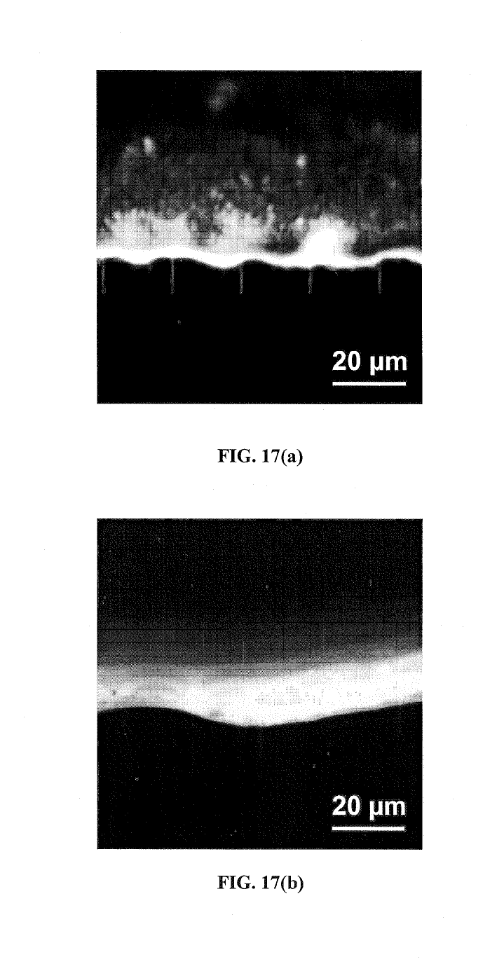

To verify performance of the fabricated nanochannels, nanochannels 190 that were 70 nm wide, 180 nm deep, and spaced 20 μm apart were employed in the open channel configuration for a diffusion experiment. This experiment used a DNA quantitation kit (Invitrogen Quant-iT™ PicoGreen® dsDNA, Carlsbad, Calif.) including a fluorophoric intercalating dye with identical excitation and emission wavelengths of fluorescein (excitation: ˜480 nm and emission: ˜520 nm). During the experiment, the standard λ-DNA provided in the kit was diluted into a 2 μg/mL working solution in TE buffer (10 mM Tris-HCl, 1 mM EDTA, pH 7.5), and the stock Quant-iT™ PicoGreen® reagent provided in dimethyl sulfoxide (DMSO) was diluted 200-fold using TE buffer. Then a final DNA assay solution (1 μg/mL) was obtained by mixing the 2 μg/mL DNA working solution and the diluted Quant-iT™ PicoGreen® reagent in a 1:1 ratio. When a drop of the final DNA assay (1 μL) was gently placed on nanochannels 190, the solution was introduced into nanochannels 190. After the solution gradually dried, the DNA molecules in the nanochannels were investigated by an epi-fluorescence microscope (Olympus BX41, Center Valley, Pa.). For comparison, fluorescein (Sigma-Aldrich, Milwaukee, Wis.) was diluted to a concentration of 100 μg/mL (0.30 mM) and introduced into the nanochannels. When the DNA molecules treated with PicoGreen intercalating dye were introduced into nanochannels 190, uniform fluorescence intensity was observed around a channel inlet, as shown in FIG. 17(a). On the other hand, the intensity of fluorescein alone was gradually decreased from the inception point due to the diffusion of the fluorescein particles, as shown in FIG. 17(b).

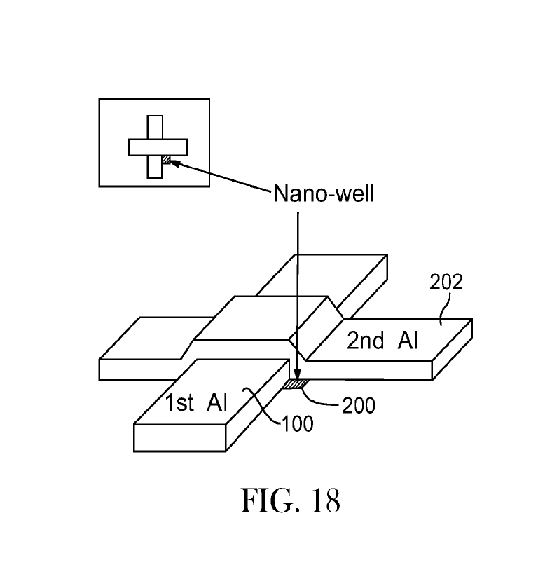

By performing multiple shadow edge depositions, the compensated SEL method can be extended to fabricate zero-dimensional nanostructures such as nanowells 196, or two-dimensional nanostructures such as arrays of nanodots 198 and crossed nanowire grids. With reference to FIG. 18, a square shadow 200 is cast by an inside corner 201 of a shadowing layer or layers of material. Compared to fabrication of the one-dimensional structures using the methods described herein, the fabrication of zero-dimensional nanostructures requires additional steps, because corner 101 formed by conventional photolithography may not be sufficiently sharp due to diffraction effects. To fabricate a sharp corner 101, two layers of Al are patterned. First Al layer 100 is evaporated and etched to create a line pattern having a first shadow edge 116. Subsequently, a second Al layer 202 is patterned on top of the first Al pattern by a conventional lift-off process (involving steps of applying photoresist, lithographic exposure, deposition of the second layer of Al, then developing and lift-off of the resist) to thereby form a second edge transverse to the first edge.

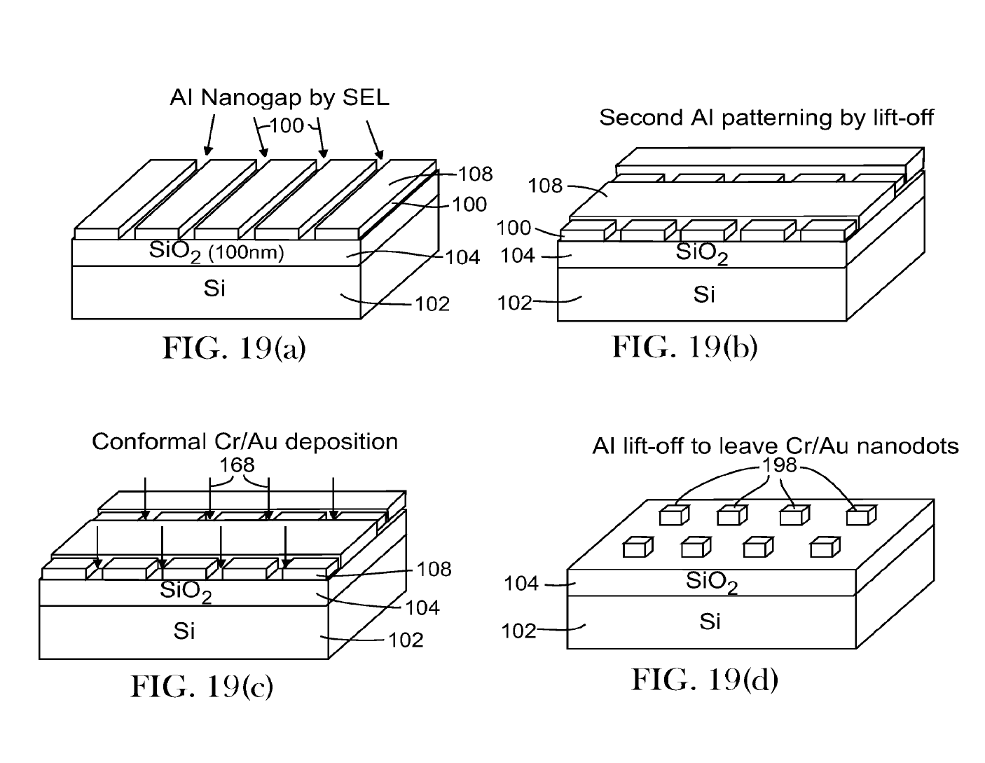

On top of the pattern shown in FIG. 18, two evaporative shadow deposition steps may then be performed from two different incident angles corresponding to the orientation of the Al lines, to thereby define 2-d nanowells 196 (dot-shaped nanogaps), as shown in FIG. 19b. Once a nanowell 196 is formed, depositing a metal such as Cr or Au to fill in the gaps, followed by a liftoff process similar to that used to form 1-d nanowires, results in an array of metal nanodots 198 shown in FIG. 19d that may be used as electrical contacts.

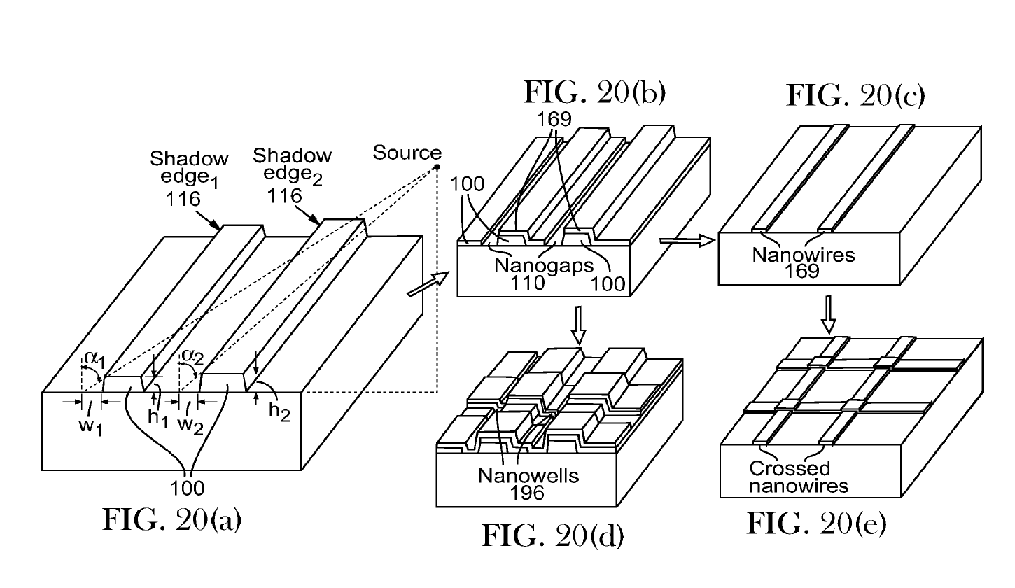

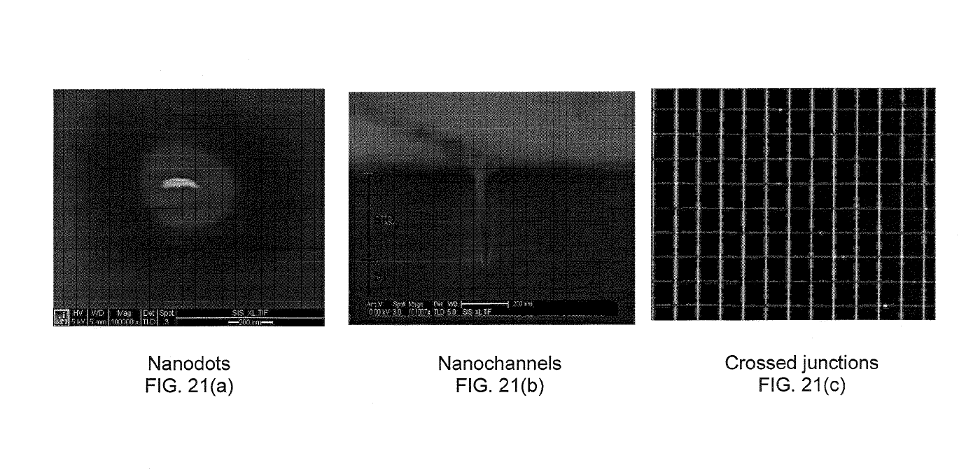

With reference to FIGS. 20 and 21, a series of schematics FIG. 20(a)-20(e) summarizes and links the distinctive features of the SEL method disclosed herein. FIG. 20(a) illustrates the multi-level tapered shadow edges 116 used to make uniform nanogaps 110 (FIG. 20b) enabled by the compensation technique. Uniform nanogaps 110 may then serve as a template for forming intermediate 1-dimensional nanowires (FIG. 20(c)) by engaging a liftoff process to reverse the nanogap pattern. Repeating the compensated SEL with multiple rounds of shadow evaporation followed by deposition and liftoff, if desired, produces zero-dimensional nanodots 198 or two-dimensional crossed nanowires as conceptualized in FIGS. 20(d) and 20(e), and as documented in corresponding top view SEM micrographs in FIGS. 21(a)-21(c).

### Edge Roughness

Critical factors determining the resolution of SEL include the roughness of pre-patterned shadow edges 116 and the roughness of nanogaps 110 such as those shown in FIGS. 10(b)-10(d). The roughness of shadow edges 116 may be transferred to second Al layer 108 during the shadow evaporation step. In addition, the roughness of the nanogaps increases during shadow evaporation as the formation of cornice 150 progresses. Because cornice 150 is unevenly generated by the adhesion, hopping, and diffusion of evaporating Al atoms, the roughness of nanogaps 110 is further increased.

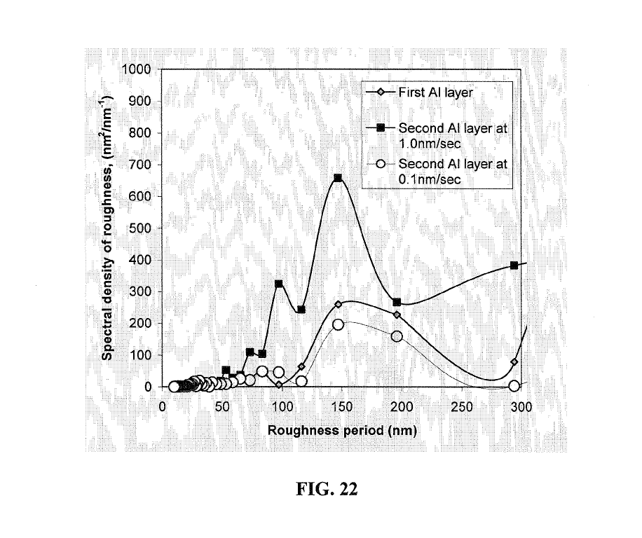

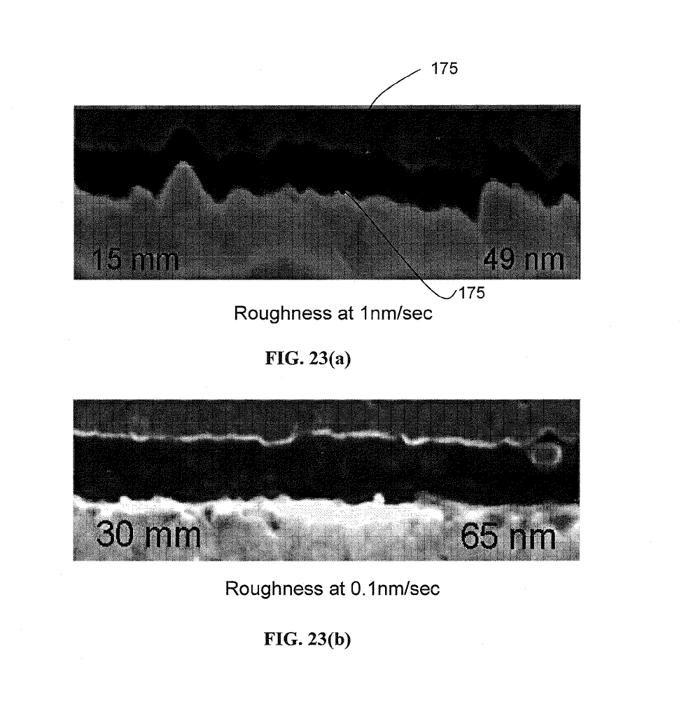

To improve patterning quality, various strategies have been attempted to reduce the edge roughness of nanogaps 110. Roughness variance of 5 nm or less may be obtained by using controlled etching and annealing to smooth the patterned edges. Rough edges 174 may be removed by controlled Al etching of first Al layer 100. The controlled diffusion of Al etchant under a photoresist layer may help smooth the patterned edge. Annealing first Al layer 100 at 450° C. for 30 minutes in a nitrogen (N₂) environment may reduce dislocations and crystallized Al layers, and may also help produce a more uniform pattern in first Al layer. Replacing Al with a high melting temperature material such as Cr produced smoother 10 nm gaps across a 100 mm wafer. One of the most effective methods of reducing nanogap roughness, however, is to reduce the Al evaporation rate, in the present case, from a rate of 1 nm/s to 0.1 nm/s. With reference to FIG. 22, edge roughness calculated using a Fast Fourier Transform method is approximately equal for both first and second Al layers when the deposition rate of the second Al layer is ten times slower. Corresponding SEM images are shown in FIGS. 23(a) and 23(b)

It will be obvious to those having skill in the art that many changes may be made to the details of the above-described embodiments without departing from the underlying principles of the invention. The scope of the present invention should, therefore, be determined only by the following claims.

1. A method for use in creating uniform nanoscale features on a substrate, the method comprising:
creating a shadow mask on the substrate by depositing and patterning a first layer of a first material including multiple mask structures having a varying height such that the height of each mask structure is a function of its position on the substrate;
depositing onto the substrate a second layer of a second material by directional vapor deposition at an oblique angle of incidence so that the mask structures cast, over exposed portions of the substrate, shadows beyond which the second material accumulates to form the second layer, and within which the substrate remains shielded from deposition of the second material to leave nanogaps of exposed substrate; and
positioning the substrate so that the structures are oriented to compensate, during deposition of the second layer, for geometric variation in the oblique angle of incidence across the substrate.

2. The method of claim 1, in which the shadow mask is created using a lithography technique.

3. The method of claim 1 or 2, in which the shadow mask is tapered.

4. The method of claim 3, in which the tapered shadow mask is formed by nonconformal deposition of the first layer.

5. The method of claim 1, in which the first material is aluminum.

6. The method of claim 1 or 5, in which the second material is aluminum.

7. The method of claim 1, in which the substrate comprises layers of material including silicon and silicon dioxide.

8. The method of claim 1, in which the substrate comprises crystalline and amorphous layers.

9. The method of claim 1, further comprising using the nanogaps to fabricate zero-, one-, or two-dimensional negative relief nanostructures in the form of holes, pores, channels, or wells, by etching the substrate at the nanogaps.

10. The method of claim 1, further comprising using the nanoscale features to fabricate zero-, one-, or two-dimensional positive relief nanostructures in the form of wires, dots, and curved shapes using a pattern reversal technique.

11. The method of claim 10, in which the nanostructures are made of one of a metal, single crystal silicon, poly-silicon, or other semiconducting material.

12. The method of claim 1, in which either or both of the shadow mask and the evaporated material are metallic.

13. The method of claim 1, further comprising rotating the substrate and repeating the directional vapor deposition to pattern nanofeatures by double shadow evaporation.

14. The method of claim 1, in which the deposition rate of the second material in forming the second layer is adjusted to control edge roughness of the nanofeatures.

15. The method of claim 14, in which the deposition rate of the second material in forming the second layer is slower than 1 nm per second.

16. A collection of nanoscale structures formed on a substrate the structures each having a feature of a nominal size in the range of 2 nm to 100 nm, the features having a maximum size deviation from the nominal size of less than 10 percent of the nominal size for every 4 inches of substrate.
